(19) United States
(12) Patent Application Publication
(10) Pub. No.: US 2010/0252091 A1
(43) Pub. Date: Oct. 7, 2010

(54) SOLAR ELECTRICITY GENERATION SYSTEM

(76) Inventors: Sagie Tsadka, Mobile Post Emek Sorek (IL); Roy Segev, Mevaseret Zion (IL); Piter Migalovich, Rehovot (IL); Ori Levin, Tel Aviv (IL); Ezri Tarazi, Shoham (IL); Robert Whelan, Australian Capital Territory (AU)

Correspondence Address: LADAS & PARRY LLP, 224 SOUTH MICHIGAN AVENUE, SUITE 1600, CHICAGO, IL, 60604, US

(21) Appl. No.: 12/677,208

(22) PCT Filed: Sep. 10, 2008
(86) PCT No.: PCT/IL08/01214

§ 371 Date: Jun. 24, 2010

(30) Foreign Application Priority Data
Sep. 10, 2007 (US) 11/852595

(51) Int. Cl. H01L 31/052; H01L 31/00

(52) U.S. Cl. 136/246; 136/259

(57) ABSTRACT

A solar electricity generation system including a solar energy-to-electricity converter having a solar energy receiving surface including at least an electricity-generating solar energy receiving surface and a plurality of reflectors arranged to reflect solar energy directly onto the solar energy receiving surface, each of the plurality of reflectors having a reflecting surface which is configured and located and aligned with respect to the solar energy receiving surface to reflect specular solar radiation with a high degree of uniformity onto the solar energy receiving surface, the configuration, location and alignment of each of the reflectors being such that the geometrical projection of each reflecting surface is substantially coextensive with the electricity-generating solar energy receiving surface.

### REFERENCE TO RELATED APPLICATIONS

Reference is made to U.S. patent application Ser. No. 11/852,595, filed Sep. 10, 2007 and entitled SOLAR ELECTRICITY GENERATION SYSTEM, the disclosure of which is hereby incorporated by reference and priority of which is hereby claimed pursuant to 37 CFR 1.78(a) (1) and (2)(i).

### FIELD OF THE INVENTION

The present invention relates to solar electricity generation systems generally.

### BACKGROUND OF THE INVENTION

The following U.S. patents and published patent applications are believed to represent the current state of the art:

U.S. Pat. Nos. 7,173,179; 7,166,797; 7,109,461; 7,081,584; 7,077,532; 7,076,965; 6,999,221; 6,974,904; 6,953,038; 6,945,063; 6,897,423; 6,881,893; 6,870,087; 6,831,221; 6,828,499; 6,820,509; 6,818,818; 6,803,514; 6,800,801; 6,799,742; 6,774,299; 6,750,392; 6,730,840; 6,717,045; 6,713,668; 6,704,607; 6,700,055; 6,700,054; 6,696,637; 6,689,949; 6,686,533; 6,661,818; 6,653,552; 6,653,551; 6,620,995; 6,607,936; 6,604,436; 6,597,709; 6,583,349; 6,580,027; 6,559,371; 6,557,804; 6,552,257; 6,548,751; 6,541,694; 6,532,953; 6,530,369; 6,528,716; 6,525,264; 6,515,217; 6,498,290; 6,489,553; 6,481,859; 6,476,312; 6,472,593; 6,469,241; 6,452,089; 6,443,145; 6,441,298; 6,407,328; 6,384,320; 6,384,318; 6,380,479; 6,372,978; 6,367,259; 6,365,823; 6,349,718; 6,333,458; 6,323,415; 6,291,761; 6,284,968; 6,281,485; 6,268,558; 6,265,653; 6,265,242; 6,252,155; 6,239,354; 6,227,673; 6,225,551; 6,207,890; 6,201,181; 6,196,216; 6,188,012; 6,178,707; 6,162,985; 6,140,570; 6,111,190; 6,091,020; 6,080,927; 6,075,200; 6,073,500; 6,067,982; 6,061,181; 6,057,505; 6,043,425; 6,036,323; 6,034,319; 6,020,554; 6,020,553; 6,015,951; 6,015,950; 6,011,215; 6,008,449; 5,994,641; 5,979,834; 5,959,787; 5,936,193; 5,919,314; 5,902,417; 5,877,874; 5,851,309; 5,727,585; 5,716,442; 5,704,701; 5,660,644; 5,658,448; 5,646,397; 5,632,823; 5,614,033; 5,578,140; 5,578,139; 5,577,492; 5,560,700; 5,538,563; 5,512,742; 5,505,789; 5,498,297; 5,496,414; 5,493,824; 5,460,659; 5,445,177; 5,437,736; 5,409,550; 5,404,869; 5,393,970; 5,385,615; 5,383,976; 5,379,596; 5,374,317; 5,353,735; 5,347,402; 5,344,497; 5,322,572; 5,317,145; 5,312,521; 5,272,570; 5,272,356; 5,269,851; 5,268,037; 5,261,970; 5,259,679; 5,255,666; 5,244,509; 5,228,926; 5,227,618; 5,217,539; 5,169,456; 5,167,724; 5,154,777; 5,153,780; 5,148,012; 5,125,983; 5,123,968; 5,118,361; 5,107,086; 5,096,505; 5,091,018; 5,089,055; 5,086,828; 5,071,596; 5,022,929; 4,968,355; 4,964,713; 4,963,012; 4,943,325; 4,927,770; 4,919,527; 4,892,593; 4,888,063; 4,883,340; 4,868,379; 4,863,224; 4,836,861; 4,834,805; 4,832,002; 4,800,868; 4,789,408; 4,784,700; 4,783,373; 4,771,764; 4,765,726; 4,746,370; 4,728,878; 4,724,010; 4,719,903; 4,716,258; 4,711,972; 4,710,588; 4,700,690; 4,696,554; 4,692,683; 4,691,075; 4,687,880; 4,683,348; 4,682,865; 4,677,248; 4,672,191; 4,670,622; 4,668,841; 4,658,805; 4,649,900; 4,643,524; 4,638,110; 4,636,579; 4,633,030; 4,628,142; 4,622,432; 4,620,913; 4,612,488; 4,611,914; 4,604,494; 4,594,470; 4,593,152; 4,586,488; 4,567,316; 4,559,926; 4,559,125; 4,557,569; 4,556,788; 4,547,432; 4,529,830; 4,529,829; 4,519,384; 4,516,018; 4,511,755; 4,510,385; 4,500,167; 4,494,302; 4,491,681; 4,482,778; 4,477,052; 4,476,853; 4,469,938; 4,465,734; 4,463,749; 4,456,783; 4,454,371; 4,448,799; 4,448,659; 4,442,348; 4,433,199; 4,432,342; 4,429,178; 4,427,838; 4,424,802; 4,421,943; 4,419,533; 4,418,238; 4,416,262; 4,415,759; 4,414,095; 4,404,465; 4,395,581; 4,392,006; 4,388,481; 4,379,944; 4,379,324; 4,377,154; 4,376,228; 4,367,403; 4,367,366; 4,361,758; 4,361,717; 4,354,484; 4,354,115; 4,352,948; 4,350,837; 4,339,626; 4,337,759; 4,337,758; 4,332,973; 4,328,389; 4,325,788; 4,323,052; 4,321,909; 4,321,417; 4,320,288; 4,320,164; 4,316,448; 4,316,084; 4,314,546; 4,313,023; 4,312,330; 4,311,869; 4,304,955; 4,301,321; 4,300,533; 4,291,191; 4,289,920; 4,284,839; 4,283,588; 4,280,853; 4,276,122; 4,266,530; 4,263,895; 4,262,195; 4,256,088; 4,253,895; 4,249,520; 4,249,516; 4,246,042; 4,245,895; 4,245,153; 4,242,580; 4,238,265; 4,237,332; 4,236,937; 4,235,643; 4,234,354; 4,230,095; 4,228,789; 4,223,214; 4,223,174; 4,213,303; 4,210,463; 4,209,347; 4,209,346; 4,209,231; 4,204,881; 4,202,004; 4,200,472; 4,198,826; 4,195,913; 4,192,289; 4,191,594; 4,191,593; 4,190,766; 4,180,414; 4,179,612; 4,174,978; 4,173,213; 4,172,740; 4,172,739; 4,169,738; 4,168,696; 4,162,928; 4,162,174; 4,158,356; 4,153,476; 4,153,475; 4,153,474; 4,152,174; 4,151,005; 4,148,299; 4,148,298; 4,147,561; 4,146,785; 4,146,784; 4,146,408; 4,146,407; 4,143,234; 4,140,142; 4,134,393; 4,134,392; 4,132,223; 4,131,485; 4,130,107; 4,129,458; 4,128,732; 4,118,249; 4,116,718; 4,115,149; 4,114,592; 4,108,154; 4,107,521; 4,106,952; 4,103,151; 4,099,515; 4,090,359; 4,086,485; 4,082,570; 4,081,289; 4,078,944; 4,075,034; 4,069,812; 4,062,698; 4,061,130; 4,056,405; 4,056,404; 4,052,228; 4,045,246; 4,042,417; 4,031,385; 4,029,519; 4,021,323; 4,021,267; 4,017,332; 4,011,854; 4,010,614; 4,007,729; 4,003,756; 4,002,499; 3,999,283; 3,998,206; 3,996,460; 3,994,012; 3,991,740; 3,990,914; 3,988,166; 3,986,490; 3,986,021; 3,977,904; 3,977,773; 3,976,508; 3,971,672; 3,957,031; 3,923,381; 3,900,279; 3,839,182; 3,833,425; 3,793,179; 3,783,231; 3,769,091; 3,748,536; 3,713,727; 3,615,853; 3,509,200; 3,546,606; 3,544,913; 3,532,551; 3,523,721; 3,515,594; 3,490,950; 3,427,200; 3,419,434; 3,400,207; 3,392,304; 3,383,246; 3,376,165; 3,369,939; 3,358,332; 3,350,234; 3,232,795; 3,186,873; 3,152,926; 3,152,260; 3,134,906; 3,071,667; 3,070,699; 3,018,313; 2,904,612; 2,751,816; 514,669; RE30,384 and RE29,833;

U.S. Published Patent Applications 2007/0035864; 2007/0023080; 2007/0023079; 2007/0017567; 2006/0283497; 2006/0283495; 2006/0266408; 2006/0243319; 2006/0231133; 2006/0193066; 2006/0191566; 2006/0185726; 2006/0185713; 2006/0174930; 2006/0169315; 2006/0162762; 2006/0151022; 2006/0137734; 2006/0137733; 2006/0130892; 2006/0107992; 2006/0124166; 2006/0090789; 2006/0086838; 2006/0086383; 2006/0086382; 2006/0076048; 2006/0072222; 2006/0054212; 2006/0054211; 2006/0037639; 2006/0021648; 2005/0225885; 2005/0178427; 2005/0166953; 2005/0161074; 2005/0133082; 2005/0121071; 2005/0091979; 2005/0092360; 2005/0081909; 2005/0081908; 2005/0046977; 2005/0039791; 2005/0039788; 2005/0034752; 2005/0034751; 2005/0022858; 2004/0238025; 2004/0231716; 2004/0231715; 2004/0194820; 2004/0187913; 2004/0187908; 2004/0187907; 2004/0187906; 2004/0173257; 2004/0173256; 2004/0163699; 2004/0163697; 2004/0134531; 2004/0123895; 2004/0118449; 2004/0112424; 2004/0112373; 2004/0103938; 2004/0095658; 2004/0085695; 2004/0084077; 2004/0079863; 2004/0045596; 2004/0031517; 2004/0025931; 2004/0021964; 2004/0011395; 2003/0213514; 2003/0201008; 2003/0201007; 2003/0156337; 2003/0140960; 2003/0137754; 2003/0116184; 2003/0111104; 2003/0075213; 2003/0075212; 2003/0070704; 2003/0051750; 2003/0047208; 2003/0034063; 2003/0016457; 2003/0015233; 2003/0000567; 2002/0189662; 2002/0179138; 2002/0139414; 2002/0121298; 2002/0075579; 2002/0062856; 2002/0007845; 2001/0036024; 2001/0011551; 2001/0008144; 2001/0008143; 2001/0007261;

### SUMMARY OF THE INVENTION

The present invention seeks to provide improved solar electricity generation systems.

There is thus provided in accordance with a preferred embodiment of the present invention a solar electricity generation system including a solar energy-to-electricity converter having a solar energy receiving surface including at least an electricity-generating solar energy receiving surface and a plurality of reflectors arranged to reflect solar energy directly onto the solar energy receiving surface, each of the plurality of reflectors having a reflecting surface which is configured and located and aligned with respect to the solar energy receiving surface to reflect specular solar radiation with a high degree of uniformity onto the solar energy receiving surface, the configuration, location and alignment of each of the reflectors being such that the geometrical projection of each reflecting surface is substantially coextensive with the electricity-generating solar energy receiving surface.

Preferably, at least 90% of the specular solar radiation reflected by the reflectors is reflected onto the electricity-generating solar energy receiving surface.

Preferably, the solar energy receiving surface also includes a heat-generating solar energy receiving surface. Additionally, nearly 100% of the specular solar radiation reflected by the reflectors is reflected onto the solar energy receiving surface.

Preferably, no intermediate optics are interposed between the reflecting surfaces and the solar energy receiving surface.

Preferably, the solar electricity generation system also includes an automatic transverse positioner operative to automatically position the electricity-generating solar energy receiving surface and the heat-generating solar energy receiving surface relative to the plurality of reflectors, thereby to enable precise focusing of solar energy thereon, notwithstanding misalignments of the reflector assembly. Additionally, the automatic transverse positioner receives inputs relating to voltage and current produced by the solar energy-to-electricity converter and is operative to fine tune the location of the plurality of reflectors to optimize the power production of the system based on the inputs.

Preferably, the solar electricity generation system also includes a dual-axis sun tracking mechanism for positioning the solar electricity generation system such that the plurality of reflectors optimally face the sun. Additionally, the dual-axis sun tracking mechanism includes a rotational tracker and a positional tracker.

Preferably, the dual-axis sun tracking mechanism receives inputs relating to voltage and current produced by the solar energy-to-electricity converter and is operative to fine tune the location of the plurality of reflectors to optimize the power production of the system based on these inputs.

Preferably, the electricity-generating solar energy receiving surface includes a plurality of photovoltaic cells. Additionally, the photovoltaic cells are individually encapsulated by a protective layer. Alternatively, the electricity-generating solar energy receiving surface is encapsulated by a protective layer.

Preferably, the solar electricity generation system also includes a reflector support surface and the plurality of reflectors are attached to the reflector support surface using clips. Additionally, the reflector support surface includes a plurality of slots for inserting the clips to assure proper placement of the plurality of reflectors.

There is also provided in accordance with another preferred embodiment of the present invention a solar electricity and heat generation system including a solar energy-to-electricity converter having an electricity-generating solar energy receiving surface, a heat exchanger coupled to the solar energy-to-electricity converter and having a heat-generating solar energy receiving surface, a plurality of reflectors arranged to reflect solar energy directly onto the electricity-generating solar energy receiving surface and onto the heat-generating solar energy receiving surface and a selectable positioner providing variable positioning between the plurality of reflectors and the electricity-generating solar energy receiving surface and the heat-generating solar energy receiving surface, thereby to enable selection of a proportion of solar energy devoted to electricity generation and solar energy devoted to heat generation.

Preferably, no intermediate optics are interposed between the reflecting surfaces and the solar energy receiving surface.

Preferably, the solar electricity and heat generation system also includes an automatic transverse positioner operative to automatically position the electricity-generating solar energy receiving surface and the heat-generating solar energy receiving surface relative to the plurality of reflectors, thereby to enable precise focusing of solar energy thereon, notwithstanding misalignments of the reflector assembly. Additionally, the automatic transverse positioner receives inputs relating to voltage and current produced by the solar energy-to-electricity converter and is operative to fine tune the location of the plurality of reflectors to optimize the power production of the system based on the inputs.

Preferably, the solar electricity and heat generation system also includes a dual-axis sun tracking mechanism for positioning the solar electricity and heat generation system such that the plurality of reflectors optimally face the sun. Additionally, the dual-axis sun tracking mechanism includes a rotational tracker and a positional tracker.

Preferably, the dual-axis sun tracking mechanism receives inputs relating to voltage and current produced by the solar energy-to-electricity converter and is operative to fine tune the location of the plurality of reflectors to optimize the power production of the system based on the inputs.

Preferably, the electricity-generating solar energy receiving surface includes a plurality of photovoltaic cells. Additionally, the photovoltaic cells are individually encapsulated by a protective layer. Additionally or alternatively, the electricity-generating solar energy receiving surface is encapsulated by a protective layer.

Preferably, the solar electricity and heat generation system also includes a reflector support surface and the plurality of reflectors are attached to the reflector support surface using clips. Additionally, the reflector support surface includes a plurality of slots for inserting the clips to assure proper placement of the plurality of reflectors.

### BRIEF DESCRIPTION OF THE DRAWINGS

The present invention will be understood and appreciated more fully from the following detailed description, taken in conjunction with the drawings in which:

FIGS. 1A, 1B and 1C are simplified illustrations of solar electricity generation systems constructed and operative in accordance with a preferred embodiment of the present invention in three alternative operative environments;

FIGS. 2A & 2B are simplified exploded view illustrations from two different perspectives of a preferred embodiment of a reflector portion particularly suitable for use in the solar electricity generation systems constructed and operative in accordance with a preferred embodiment of the present invention;

FIGS. 3A & 3B are simplified assembled view illustrations corresponding to FIGS. 2A & 2B respectively;

FIG. 4 is a simplified pictorial and sectional illustration showing a preferred method of attachment of reflectors to the reflector portion of FIGS. 2A-3B in accordance with another preferred embodiment of the present invention;

FIG. 5 is a simplified pictorial illustration of a preferred arrangement of mirrors in the solar electricity generation systems of the present invention;

FIG. 6 is a simplified pictorial illustration of a solar energy converter assembly constructed and operative in accordance with a preferred embodiment of the present invention;

FIG. 7 is a simplified pictorial illustration of beam paths from some of the mirrors of the reflector portion to the receiver portion of the solar energy converter assembly of FIG. 6;

FIG. 8 is a simplified exploded view illustration of a solar energy converter assembly constructed and operative in accordance with a preferred embodiment of the present invention;

FIG. 9 is a simplified assembled view illustration of the solar energy converter assembly of FIG. 8;

FIGS. 10A, 10B and 10C illustrate impingement of solar energy on the solar energy converter assembly of FIGS. 8 and 9 for three different positions of the solar energy converter assembly relative to the reflector portion of the solar electricity generation system; and

FIGS. 11A, 11B and 11C illustrate impingement of solar energy on the solar energy converter assembly of FIGS. 8 and 9 for three different positions of the solar energy converter assembly relative to the reflector portion of the solar electricity generation system.

### DETAILED DESCRIPTION OF PREFERRED EMBODIMENTS

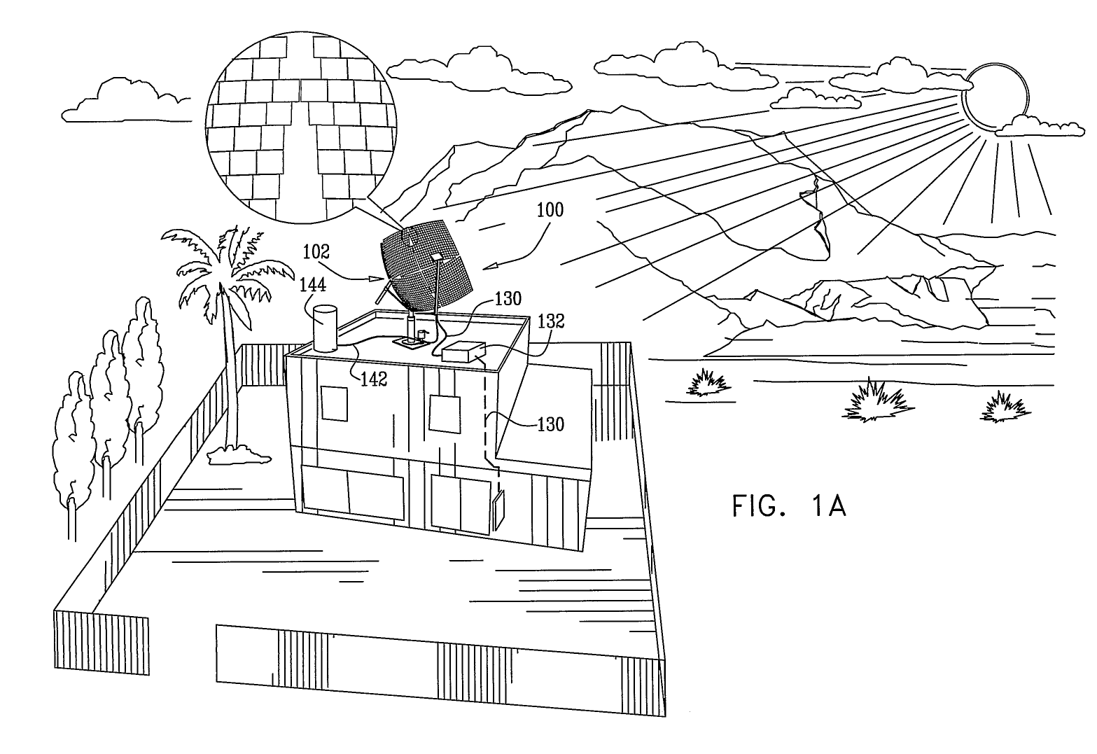

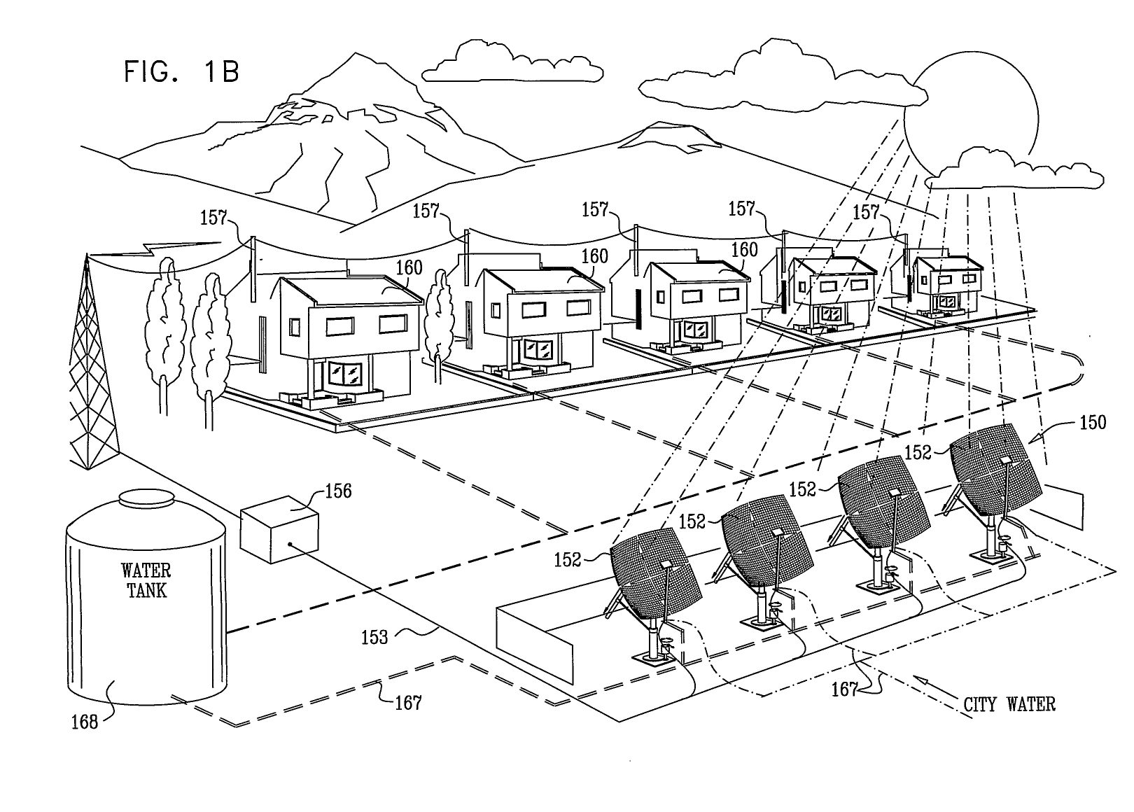

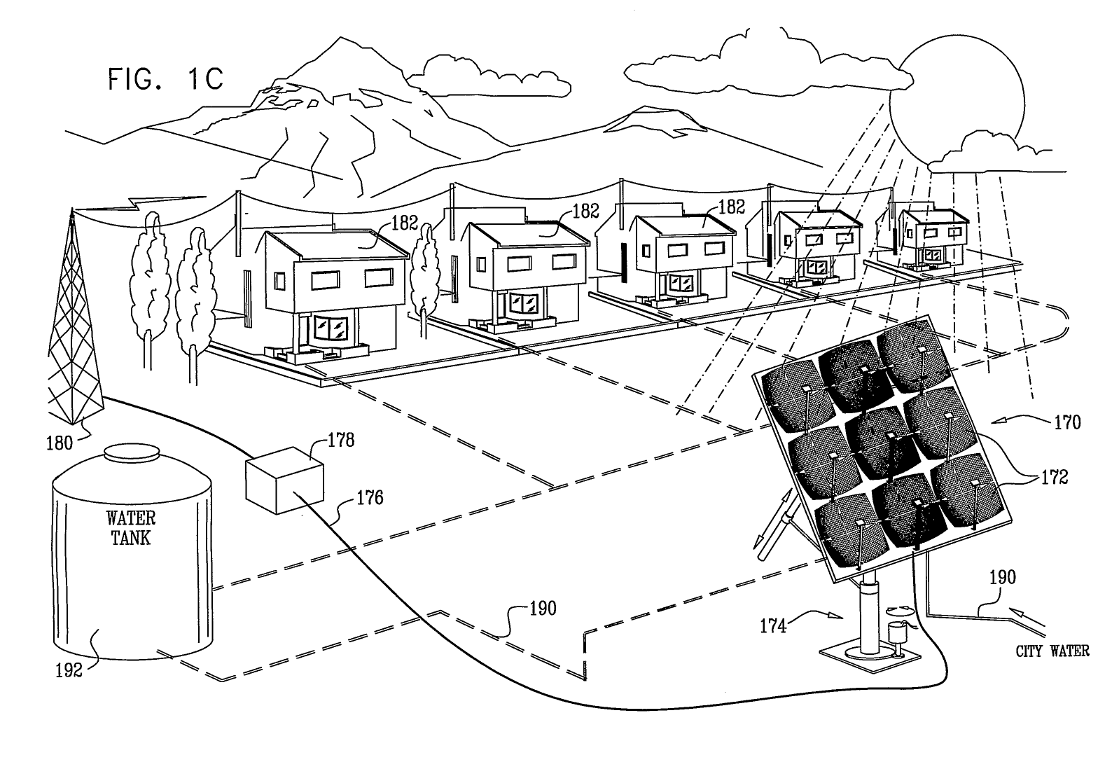

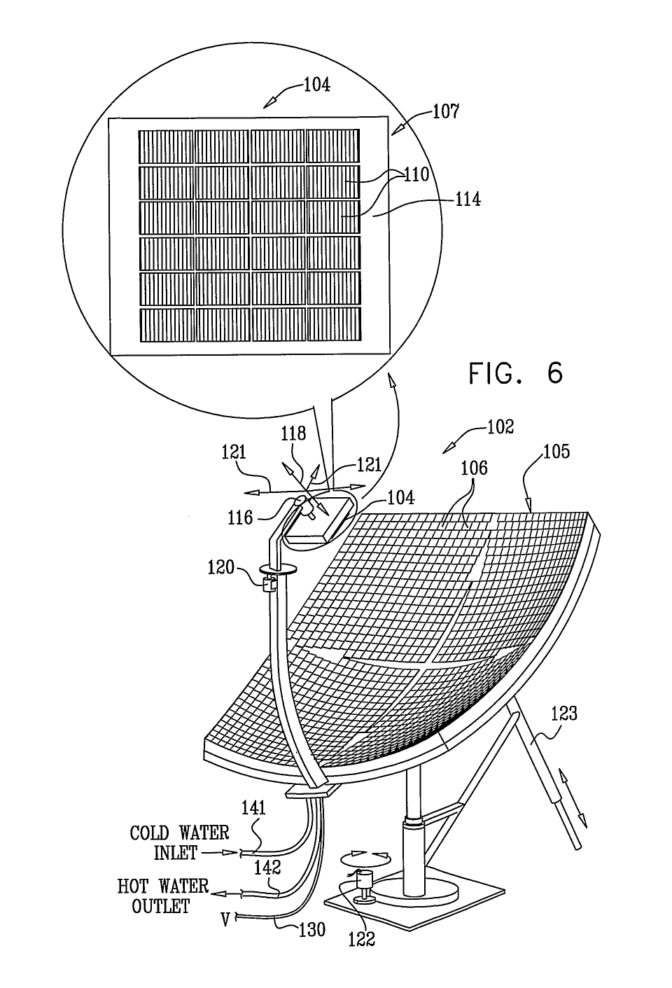

Reference is now made to FIGS. 1A, 1B & 1C, which are simplified illustrations of solar electricity generation systems constructed and operative in accordance with a preferred embodiment of the present invention in two alternative operative environments. Turning to FIG. 1A, there is seen a solar electricity generation system, generally designated by reference numeral 100. Solar electricity generation system 100 preferably includes a solar energy converter assembly 102, a preferred embodiment of which is illustrated in FIG. 6, to which specific reference is made.

As seen with clarity in FIG. 6, solar energy converter assembly 102 includes a solar energy receiving assembly 104 and a reflector assembly 105, including a plurality of reflectors 106 arranged to reflect solar energy directly onto a solar energy receiving surface 107 of the solar energy receiving assembly 104. Each of the plurality of reflectors 106 has a reflecting surface which is configured and located and aligned with respect to the solar energy receiving surface 107 to reflect specular solar radiation with a high degree of uniformity onto the solar energy receiving surface 107. The configuration, location and alignment of each of the reflectors 106 is such that the geometrical projection of each reflecting surface is substantially coextensive with the solar energy receiving surface 107.

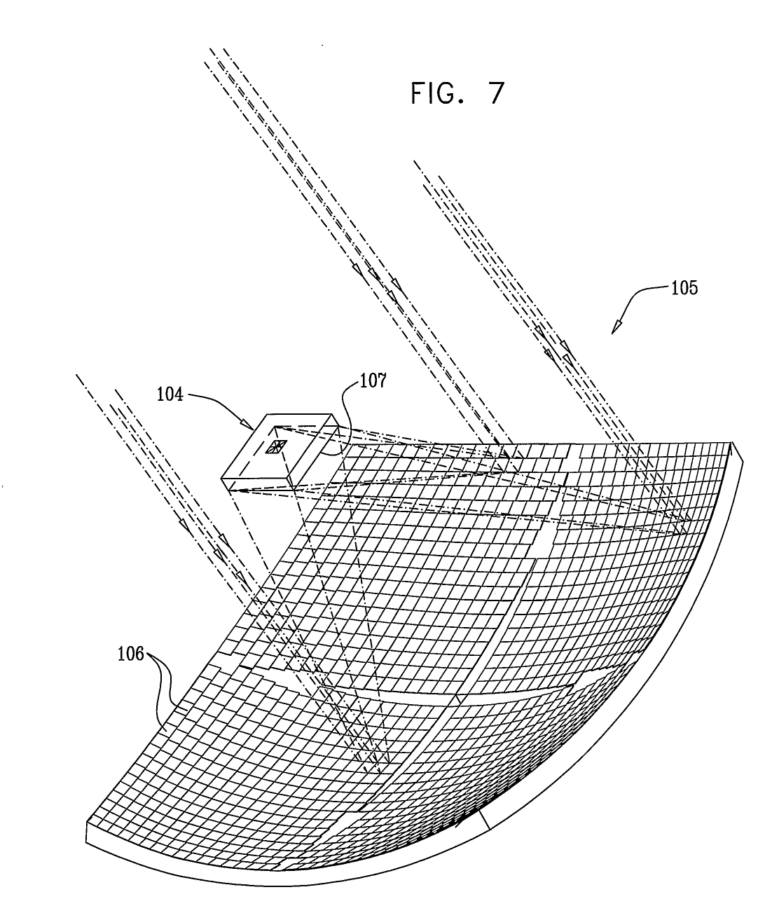

It is a particular feature of the present invention that no intermediate optics are interposed between the reflecting surfaces of reflectors 106 and the solar energy receiving surface 107. This is shown clearly in FIG. 7.

Turning now additionally to FIG. 8, it is an additional feature of a preferred embodiment of the present invention that the solar energy receiving assembly 104 includes a solar energy-to-electricity converter 108 having an electricity-generating solar energy receiving surface 110 and a heat exchanger 112, which may be active or passive, thermally coupled to the solar energy-to-electricity converter 108 and having a heat-generating solar energy receiving surface 114. Both solar energy receiving surfaces 110 and 114 are arranged to lie in a collective focal plane of the plurality of reflectors 106.

Returning to FIG. 6, it is seen that preferably there is provided a selectable Z-axis positioner 116 providing variable Z-axis positioning along a Z-axis 118 between the plurality of reflectors 106 and the solar energy receiving surface 107, thereby to enable selection of a proportion of solar energy devoted to electricity generation and solar energy devoted to heat generation.

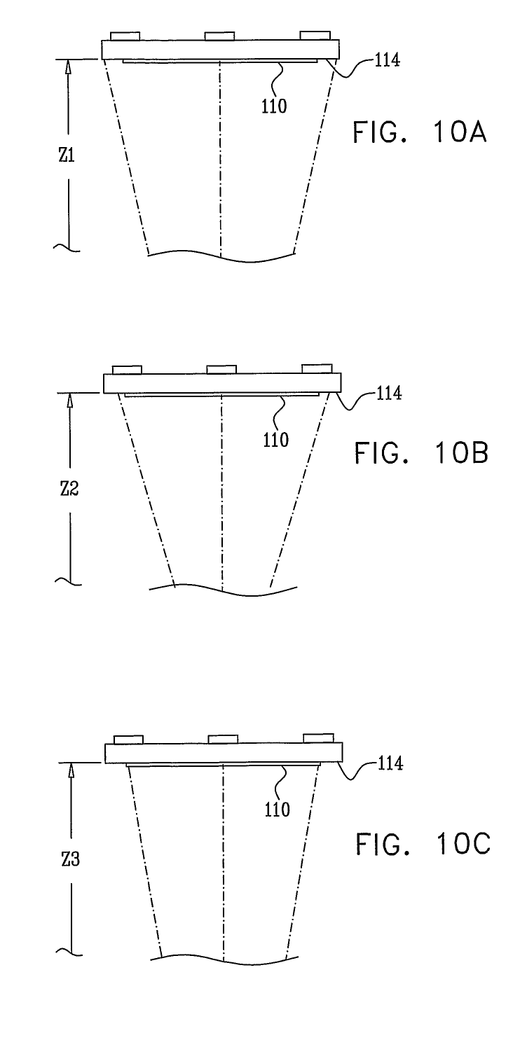

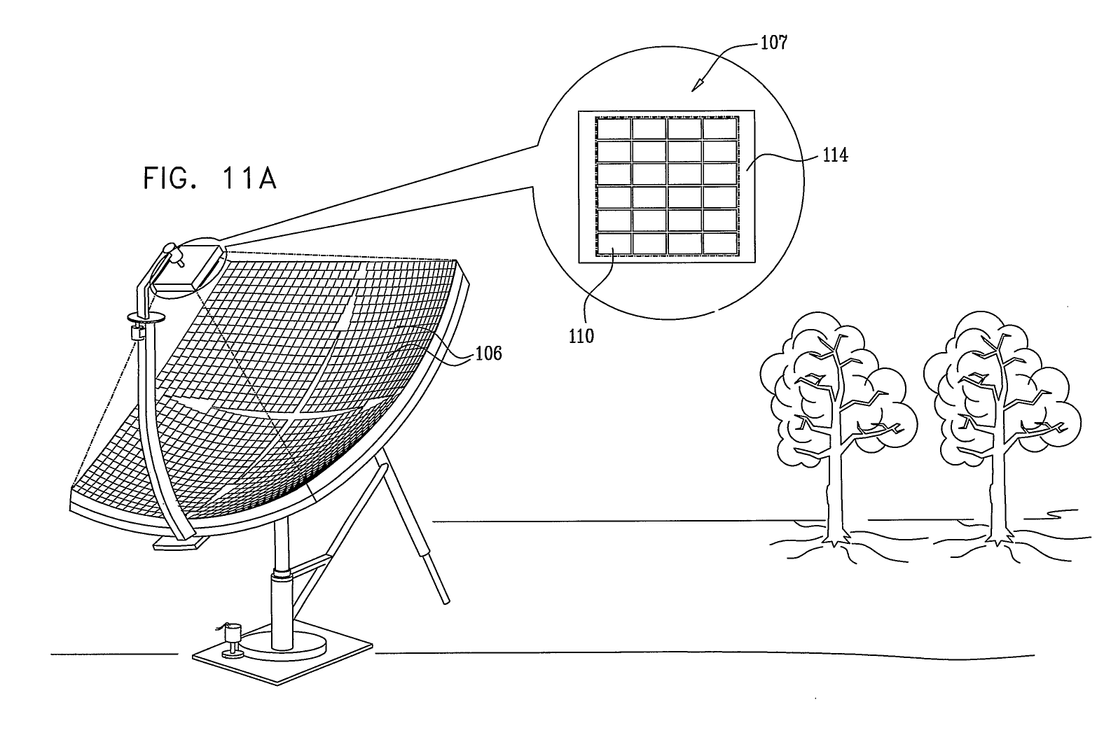

FIGS. 10A-10C show the impingement of solar energy from reflector assembly 105 for three different relative Z-axis positions: FIG. 10A shows impingement on both electricity-generating solar energy receiving surface 110 and nearly all of heat-generating solar energy receiving surface 114 when solar energy receiving surface 107 is at a distance of Z1 from the center of the reflector assembly 105; FIG. 10B shows impingement on both electricity-generating solar energy receiving surface 110 and part of heat-generating solar energy receiving surface 114 when solar energy receiving surface 107 is at a distance of Z2<Z1 from the center of the reflector assembly 105; and FIG. 10C shows impingement on only electricity-generating solar energy receiving surface 110 when solar energy receiving surface 107 is at a distance of Z3<Z2 from the center of the reflector assembly 105.

Returning to FIG. 6, it is seen that preferably there is also provided an automatic transverse positioner 120 providing positioning along axes 121 in directions transverse to Z-axis 118 between the plurality of reflectors 106 and the electricity-generating solar energy receiving surface 110 and onto the heat-generating solar energy receiving surface 114, thereby to enable precise focusing of solar energy onto surfaces 110 and 114 notwithstanding temporary or long term misalignments of the reflector assembly 105 and surfaces 110 and 114, which may occur, for example, due to wind or thermal effects. Preferably, the automatic transverse positioner 120 receives inputs relating to voltage and current produced by the solar energy-to-electricity converter 108 and is operative to fine tune the location of the solar energy receiving surface 107 to optimize the power production of the system based on these inputs.

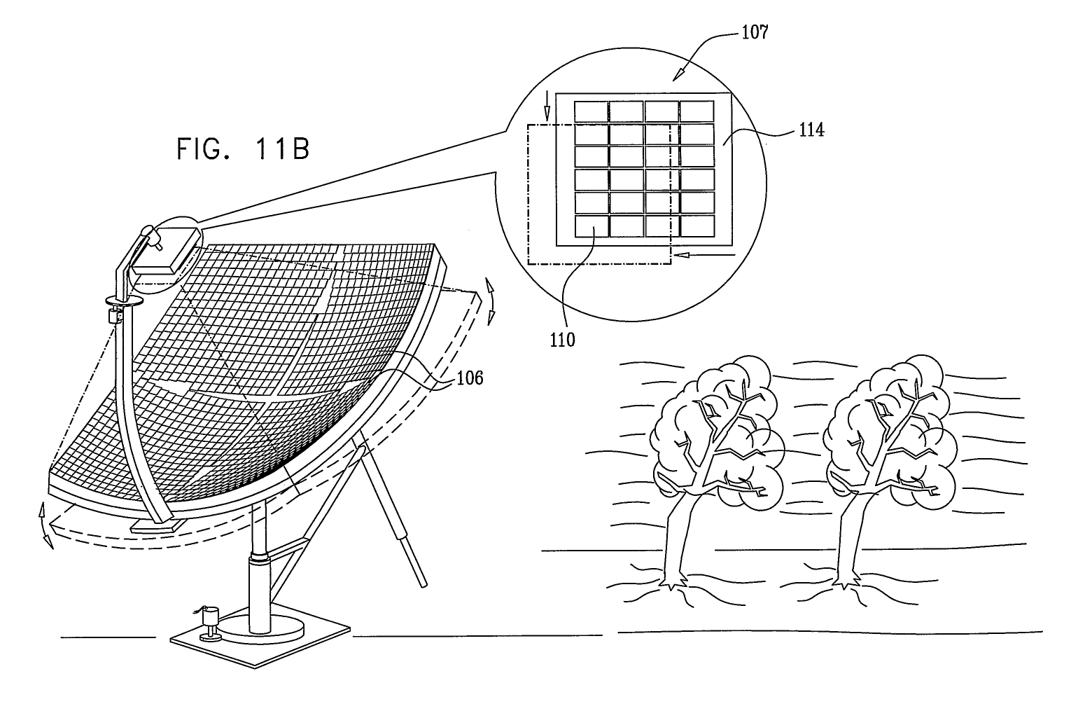

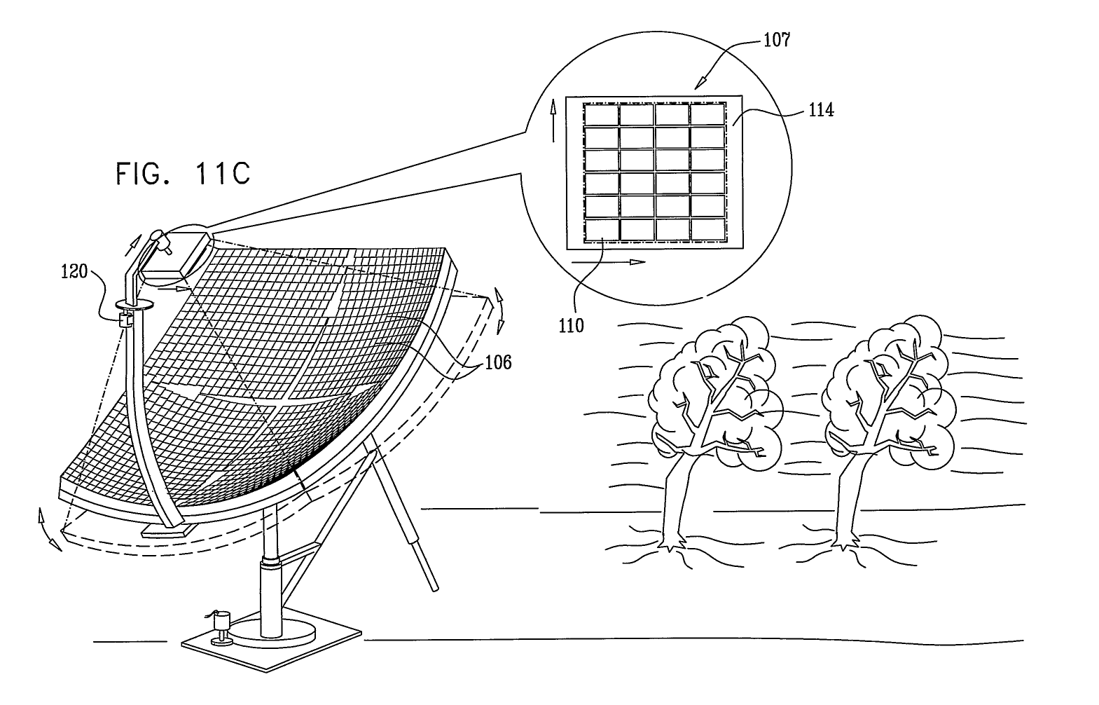

FIGS. 11A-11C illustrate automatic positioning compensation provided by automatic transverse positioner 120. FIG. 11A shows a typical preferred steady state orientation wherein the plurality of reflectors 106 precisely focus solar energy onto the electricity-generating solar energy receiving surface 110 and onto the heat-generating solar energy receiving surface 114. FIG. 11B shows the effects of a distortion in the positioning of the plurality of reflectors 106, due to wind or other environmental factors, which results in solar energy not being precisely focused onto the electricity-generating solar energy receiving surface 110 and onto the heat-generating solar energy receiving surface 114. FIG. 11C shows the result of operation of automatic transverse positioner 120 in providing real time readjustment of the position of the electricity-generating solar energy receiving surface 110 and onto the heat-generating solar energy receiving surface 114 along axes 121 to compensate for the distortion, such that the plurality of reflectors 106 precisely focus solar energy onto the electricity-generating solar energy receiving surface 110 and onto the heat-generating solar energy receiving surface 114.

Returning to FIG. 6, it is seen that additionally, there is preferably provided a dual-axis sun tracking mechanism, including a rotational tracker 122 and a positional tracker 123, for positioning the solar energy converter assembly 102 such that the reflector assembly 105 optimally faces the sun as it moves in the sky during the day and during the year.

Returning to FIG. 1A, it is seen that electricity produced by the solar energy-to-electricity converter 108 may be supplied via suitable transmission lines 130 via an inverter 132, that converts the DC power to AC power, to electrical appliances (not shown) or via a conventional dual directional electric meter (not shown) to an electricity grid (not shown). Alternatively, the electricity produced may be supplied to a storage battery (not shown) without being converted from DC power to AC power.

The dual-axis sun tracking mechanism preferably receives, via inverter 132, periodic inputs relating to voltage and current produced by solar energy-to-electricity converter 108. The dual-axis sun tracking mechanism is preferably operative to compare the inputs from different time periods to fine tune the location of the reflector assembly 105 in order to optimize the power production of the solar electricity generation system 100 and to overcome slight misalignments or any other non-perfect focusing of the sunlight from reflector assembly 105 onto solar energy receiving surface 107.

Preferably, water is circulated through the heat exchanger 112 by pipes 141 and 142 which are connected, respectively, to a water supply and a heated water storage tank 144. This heated water can be used as domestic hot water and/or for other applications, such as air conditioning and/or heating. It is appreciated that liquids other than water may be circulated through heat exchanger 112.

Reference is now made to FIG. 1B, which shows a collection 150 of solar electricity generation systems 152 of the type described above arranged to provide electrical power and heated liquid to multiple dwellings or other facilities. The electrical outputs of solar electricity generation systems 152 may be combined as shown in FIG. 1B.

Electricity produced by multiple solar energy-to-electricity converters 108 of systems 152 may be supplied via suitable transmission lines 153 to a common storage battery 156, via multiple inverters 157 or a common inverter (not shown) to multiple dwellings 160 for powering electrical appliances (not shown) therein or via a common conventional dual directional electric meter (not shown) to electricity grid (not shown).

Preferably, water is circulated through the heat exchanger 112 by pipes 167 connected to a water supply and a heated water storage tank 168. This heated water can be used as domestic hot water and/or for other applications, such as air conditioning and/or heating.

Reference is now made to FIG. 1C, which shows a collection 170 of solar electricity generation systems 172 of the type described above mounted on a common dual-axis sun tracking mechanism 174 for positioning the plurality of reflectors 106 to optimally face the sun as it moves in the sky during the day and during the year. Solar electricity generation systems 172 are preferably operative to provide electrical power and heated liquid to multiple dwellings or other facilities. The electrical outputs of solar electricity generation systems 172 may be combined as shown in FIG. 1C.

Electricity produced by multiple solar energy-to-electricity converters 108 of systems 172 may be supplied via suitable transmission lines 176 to a common storage battery 178, via multiple inverters or a common inverter 180 to multiple dwellings 182 for powering electrical appliances (not shown) therein or via a common conventional dual directional electric meter (not shown) to electricity grid (not shown).

Preferably, water is circulated through the heat exchanger 112 by pipes 190 connected to a water supply and to a heated water storage tank 192. This heated water can be used as domestic hot water and/or for other applications, such as air conditioning and/or heating.

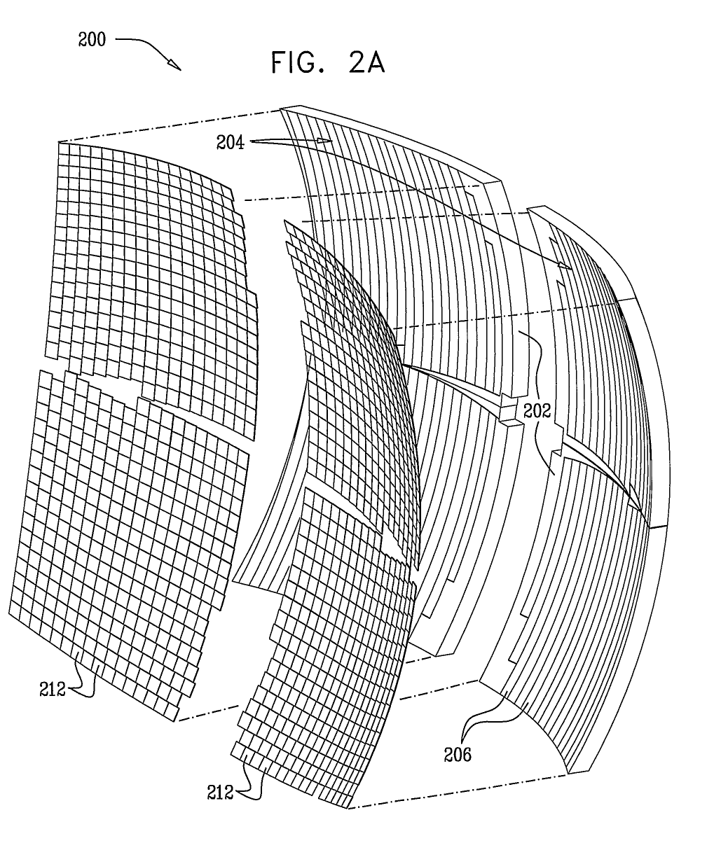

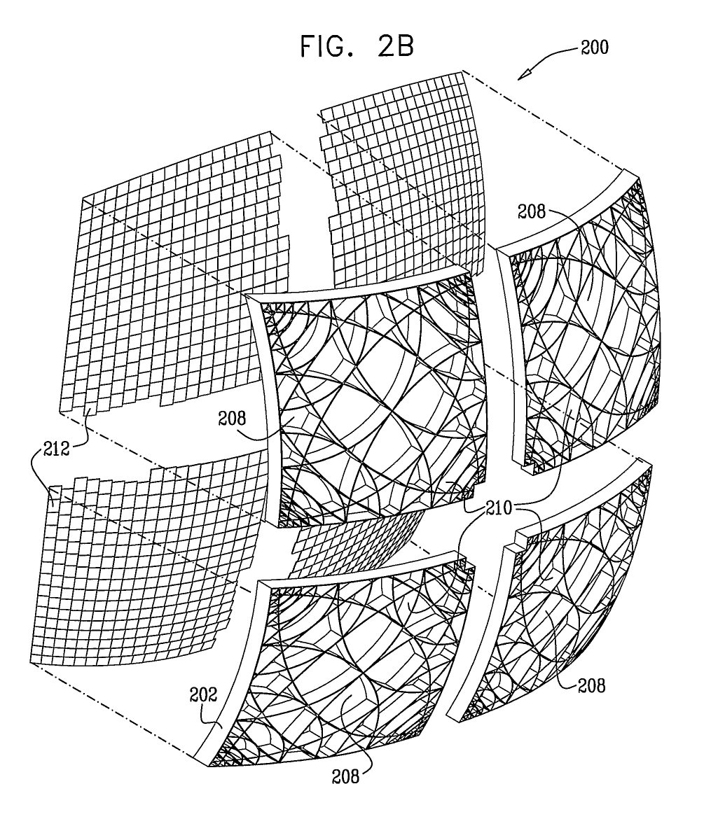

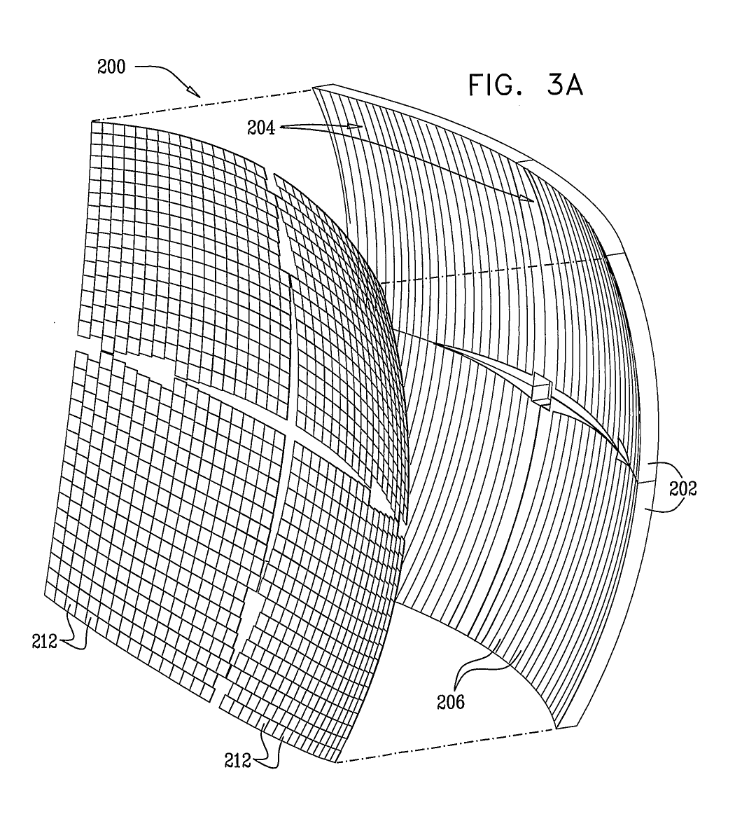

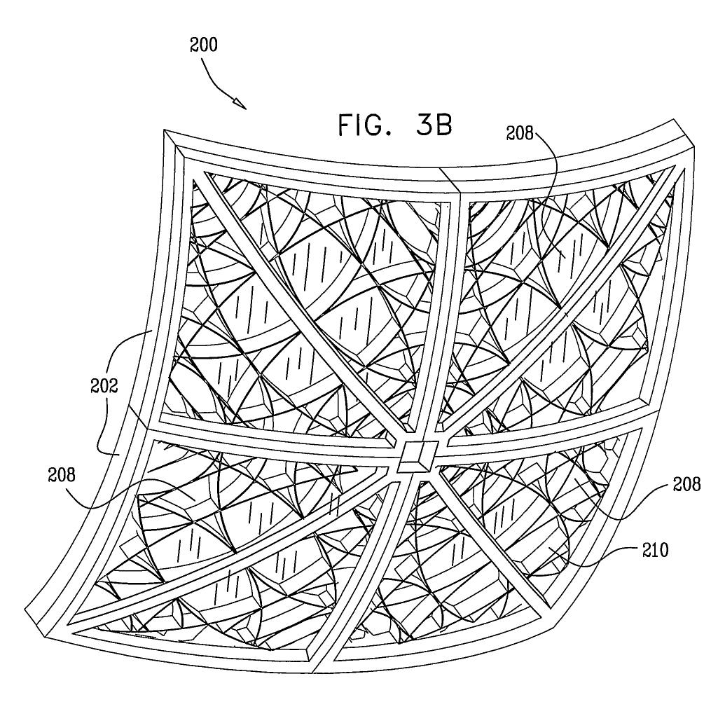

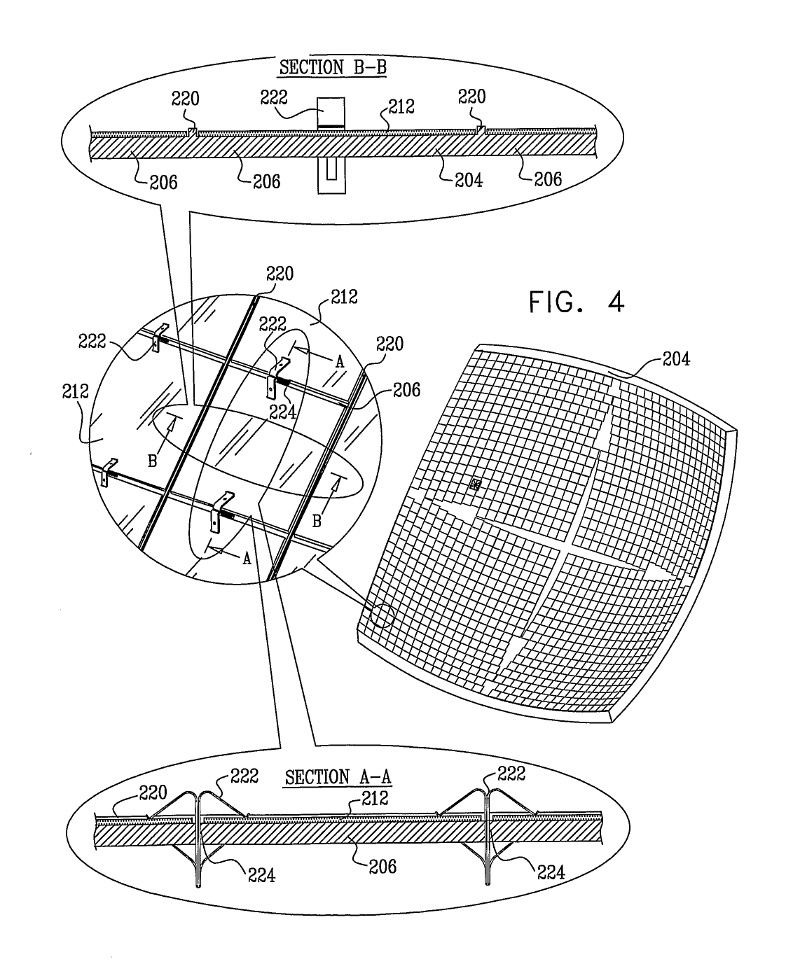

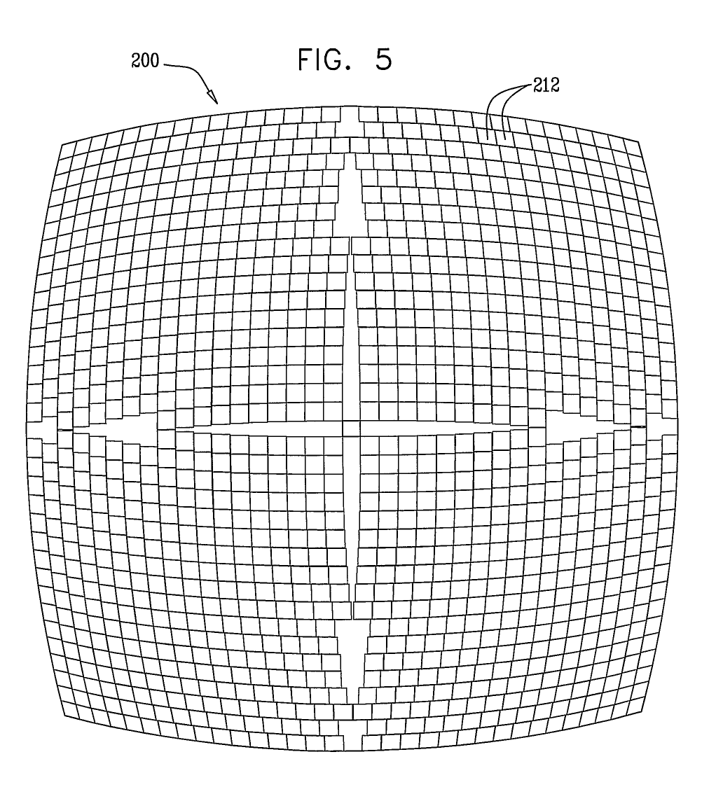

Reference is now made to FIGS. 2A & 2B, which are simplified exploded view illustrations from two different perspectives of a preferred embodiment of a reflector assembly 200, particularly suitable for use in the solar electricity generation systems constructed and operative in accordance with a preferred embodiment of the present invention; to FIGS. 3A & 3B, which are simplified assembled view illustrations corresponding to FIGS. 2A & 2B respectively; to FIG. 4, which is a simplified pictorial and sectional illustration showing a preferred method of attachment of reflectors to the reflector portion of FIGS. 2A-3B, and to FIG. 5, which is a simplified pictorial illustration of a preferred arrangement of mirrors in the solar electricity generation systems of the present invention.

As seen in FIGS. 2A-5, reflector assembly 200 preferably comprises a plurality, preferably four in number, of curved support elements 202, each of which is configured to have a reflector support surface 204 configured as a portion of a paraboloid, most preferably a paraboloid having a focal length of either 1.6 or 2.0 meters. Support elements 202 are preferably injection molded of polypropylene and include glass fibers. Preferably, the reflector support surface 204 is formed with a multiplicity of differently shaped flat individual reflector support surfaces 206, which define the precise optical positioning of the individual reflector elements. Preferably the surfaces 208 of the curved support elements 202 facing oppositely to reflector support surface 204, are formed with transverse structural ribs 210, preferably arranged in concentric circles about the center of reflector assembly 200 and about each of the outermost corners of elements 202.

A multiplicity of flat reflector elements 212 are mounted onto reflector support surface 204, each individual flat reflector element 212 being mounted onto a correspondingly shaped flat individual reflector support surface 206 formed on reflector support surface 204. It is a particular feature of the present invention that the configuration, location and alignment of each individual flat reflector element 212 is selected such that the geometrical projection of the reflecting surface of each individual flat reflector element 212 is substantially coextensive with the electricity-generating solar energy receiving surface 107 (FIG. 1A).

In a preferred embodiment of the present invention, wherein the reflector support surface 204 has a focal length of 1.6 meters, a total of approximately 1600 individual reflector elements are provided and include approximately 400 different reflector element configurations. Preferably, the configuration and arrangement of individual reflector elements on each of support elements 202 is identical. The configuration and arrangement of individual reflector elements 212 on each of support elements 202 is generally symmetric along an imaginary diagonal extending outwardly from the geometrical center of the reflector assembly 200. It is appreciated that all of the individual flat reflector elements 212 are preferably parallelograms and some of individual flat reflector elements 212, particularly those near the geometrical center of the reflector assembly 200, are squares.

As seen particularly in FIG. 4, flat reflector elements 212 are mounted onto reflector support surface 204, along flat individual reflector support surfaces 206. Flat individual reflector support surfaces 206 are preferably separated by upward protruding wall portions 220, which provide for the proper alignment of reflector elements 212 along reflector support surfaces 206. Reflector elements 212 are preferably attached to reflector support surfaces 206 using clips 222, for ease of removal in the event replacement of a specific reflector element 212 is required. Reflector support surfaces 206 are preferably configured with slots 224 providing for the placement of clips 222 and ensuring proper alignment of reflector elements 212.

It is appreciated that the provision of clips 222 and slots 224 allows for the precise alignment and attachment of reflector elements 212 to support surfaces 206, typically formed of plastic, without requiring an adhesive material, which typically degrades over time. Clips 222 and slots 224 typically allow the accuracy of reflection of solar energy from reflector elements 212 to electricity-generating solar energy receiving surface 107 and heat-generating solar energy receiving surface 110 to be maintained within a range of several mili-radians.

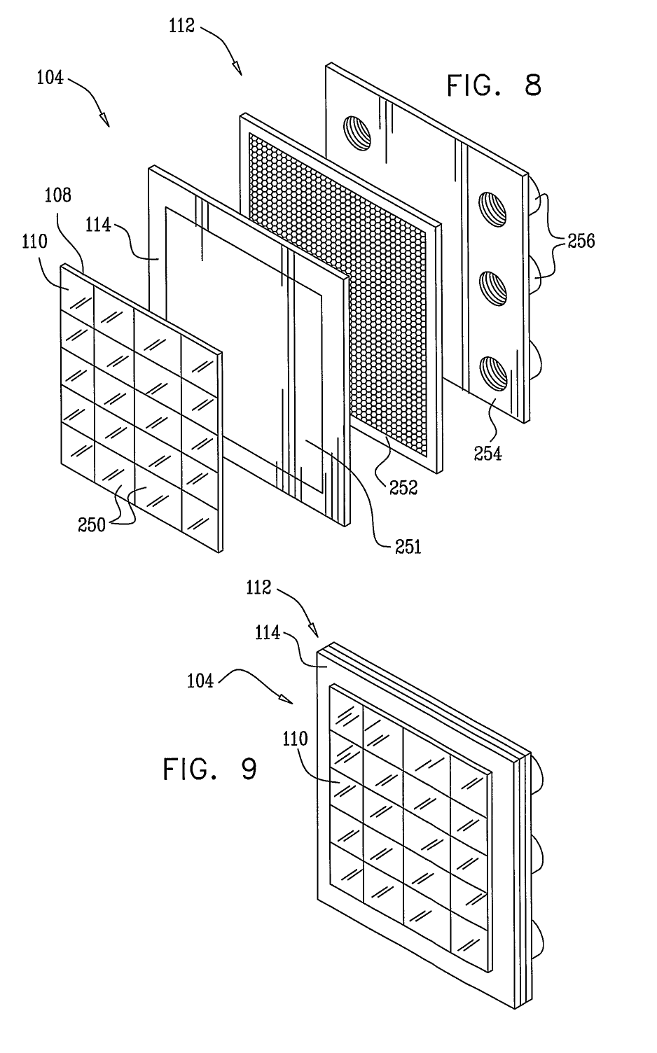

Reference is now made to FIG. 8, which is a simplified exploded view illustration of solar energy receiving assembly 104, constructed and operative in accordance with a preferred embodiment of the present invention and to FIG. 9, which is a simplified assembled view illustration of the solar energy receiving assembly 104 of FIG. 8.

As seen in FIGS. 8 and 9, solar energy receiving assembly 104 includes solar energy-to-electricity converter 108 having electricity-generating solar energy receiving surface 110, including a plurality of photovoltaic cells 250, preferably formed of a suitable semiconductor material, attached, preferably by soldering, to a heat sink portion 251, preferably thermally and mechanically coupled to heat-generating solar energy receiving surface 114 which extends peripherally with respect thereto. Heat exchanger 112 preferably includes a water flow portion 252, including multiple water channels for heat dissipation and transfer, and a water inflow/outflow portion 254 including water flow channels 256 in fluid communication with cold water inlet 141 and hot water outlet 142.

In a preferred embodiment of the present invention, as shown in FIG. 8, each of photovoltaic cells 250 is individually encapsulated by a protective layer, preferably formed of glass or other suitable material. Additionally or alternatively, electricity-generating solar energy receiving surface 110 may be encapsulated in its entirety by a protective layer, preferably formed of glass or other suitable material.

It will be appreciated by persons skilled in the art that the present invention is not limited to the features specifically described and illustrated above. Rather the scope of the present invention extends to various combinations and subcombinations of such features as well as modifications and variations thereof which would occur to persons skilled in the art upon reading the foregoing description and which are not in the prior art.

1. A solar electricity generation system comprising:
a solar energy-to-electricity converter having a solar energy receiving surface including at least an electricity-generating solar energy receiving surface; and
a plurality of reflectors arranged to reflect solar energy directly onto said solar energy receiving surface, each of said plurality of reflectors having a reflecting surface which is configured and located and aligned with respect to said solar energy receiving surface to reflect specular solar radiation with a high degree of uniformity onto said solar energy receiving surface, the configuration, location and alignment of each of said reflectors being such that the geometrical projection of each reflecting surface is substantially coextensive with said electricity-generating solar energy receiving surface.

2. A solar electricity generation system according to claim 1 and wherein at least 90% of said specular solar radiation reflected by said reflectors is reflected onto said electricity-generating solar energy receiving surface.

3. A solar electricity generation system according to claim 1 and wherein said solar energy receiving surface also comprises a heat-generating solar energy receiving surface.

4. A solar electricity generation system according to claim 3 and wherein nearly 100% of said specular solar radiation reflected by said reflectors is reflected onto said solar energy receiving surface.

5. A solar electricity generation system according to claim 1 and wherein no intermediate optics are interposed between said reflecting surfaces and said solar energy receiving surface.

6. A solar electricity generation system according to claim 1 and also comprising an automatic transverse positioner operative to automatically position said electricity-generating solar energy receiving surface and said heat-generating solar energy receiving surface relative to said plurality of reflectors, thereby to enable precise focusing of solar energy thereon, notwithstanding misalignments of said reflector assembly.

7. A solar electricity generation system according to claim 6 and wherein said automatic transverse positioner receives inputs relating to voltage and current produced by said solar energy-to-electricity converter and is operative to fine tune the location of said plurality of reflectors to optimize the power production of said system based on said inputs.

8. A solar electricity generation system according to claim 1 and also comprising a dual-axis sun tracking mechanism for positioning said solar electricity generation system such that said plurality of reflectors optimally face the sun.

9. A solar electricity generation system according to claim 8 and wherein said dual-axis sun tracking mechanism includes a rotational tracker and a positional tracker.

10. A solar electricity generation system according to claim 8 and wherein said dual-axis sun tracking mechanism receives inputs relating to voltage and current produced by said solar energy-to-electricity converter and is operative to fine tune the location of said plurality of reflectors to optimize the power production of said system based on said inputs.

11. A solar electricity generation system according to claim 1 and wherein said electricity-generating solar energy receiving surface comprises a plurality of photovoltaic cells.

12. A solar electricity generation system according to claim 11 and wherein said photovoltaic cells are individually encapsulated by a protective layer.

13. A solar electricity generation system according to claim 1 and wherein said electricity-generating solar energy receiving surface is encapsulated by a protective layer.

14. A solar electricity generation system according to claim 1 and also comprising a reflector support surface and wherein said plurality of reflectors are attached to said reflector support surface using clips.

15. A solar electricity heat generation system according to claim 14 and wherein said reflector support surface includes a plurality of slots for inserting said clips to assure proper placement of said plurality of reflectors.

16. A solar electricity and heat generation system comprising:
a solar energy-to-electricity converter having an electricity-generating solar energy receiving surface;
a heat exchanger coupled to said solar energy-to-electricity converter and having a heat-generating solar energy receiving surface;
a plurality of reflectors arranged to reflect solar energy directly onto said electricity-generating solar energy receiving surface and onto said heat-generating solar energy receiving surface; and
a selectable positioner providing variable positioning between said plurality of reflectors and said electricity-generating solar energy receiving surface and said heat-generating solar energy receiving surface, thereby to enable selection of a proportion of solar energy devoted to electricity generation and solar energy devoted to heat generation.

17. A solar electricity and heat generation system according to claim 16 and wherein no intermediate optics are interposed between said reflecting surfaces and said solar energy receiving surface.

18. A solar electricity and heat generation system according to claim 16 and also comprising an automatic transverse positioner operative to automatically position said electricity-generating solar energy receiving surface and said heat-generating solar energy receiving surface relative to said plurality of reflectors, thereby to enable precise focusing of solar energy thereon, notwithstanding misalignments of said reflector assembly.

19. A solar electricity generation system according to claim 18 and wherein said automatic transverse positioner receives inputs relating to voltage and current produced by said solar energy-to-electricity converter and is operative to fine tune the location of said plurality of reflectors to optimize the power production of said system based on said inputs.

20. A solar electricity and heat generation system according to claim 16 and also comprising a dual-axis sun tracking mechanism for positioning said solar electricity and heat generation system such that said plurality of reflectors optimally face the sun.

21. A solar electricity and heat generation system according to claim 20 and wherein said dual-axis sun tracking mechanism includes a rotational tracker and a positional tracker.

22. A solar electricity and heat generation system according to claim 20 and wherein said dual-axis sun tracking mechanism receives inputs relating to voltage and current produced by said solar energy-to-electricity converter and is operative to fine tune the location of said plurality of reflectors to optimize the power production of said system based on said inputs.

23. A solar electricity and heat generation system according to claim 16 and wherein said electricity-generating solar energy receiving surface comprises a plurality of photovoltaic cells.

24. A solar electricity and heat generation system according to claim 23 and wherein said photovoltaic cells are individually encapsulated by a protective layer.

25. A solar electricity and heat generation system according to claim 16 and wherein said electricity-generating solar energy receiving surface is encapsulated by a protective layer.

26. A solar electricity and heat generation system according to claim 16 and also comprising a reflector support surface and wherein said plurality of reflectors are attached to said reflector support surface using clips.

27. A solar electricity and heat generation system according to claim 26 and wherein said reflector support surface includes a plurality of slots for inserting said clips to assure proper placement of said plurality of reflectors.
